(19) United States
(12) Patent Application Publication
(10) Pub. No.: US 2017/0099065 A1
(43) Pub. Date: Apr. 6, 2017

(54) SCAN METHOD FOR KEYBOARDS

(71) Applicant: MSI COMPUTER(SHENZHEN) CO., LTD., Shenzhen City (CN)

(72) Inventors: Yu-Szu LEE, New Taipei City (TW); Yu-Tseng CHAO, New Taipei City (TW); Ching-Yu HO, New Taipei City (TW)

(21) Appl. No.: 14/936,034

(22) Filed: Nov. 9, 2015

(30) Foreign Application Priority Data
Oct. 6, 2015 (TW) 104132835

(51) Int. Cl. H03M 11/20; H03K 17/967

(52) U.S. Cl. CPC H03M 11/20; H03K 17/967

(57) ABSTRACT

A scan method for keyboards is firstly to set a higher voltage or a lower voltage to a keyboard scan input/output port when a low voltage signal is generated at a keyboard scan input port, and then to detect a voltage at the keyboard scan input/output port or the keyboard scan input port so as to determine whether the detected low voltage signal is a valid button-depressed signal or a noise. Further, a grounding resistor is connected electrically to the keyboard scan input/output port, and the scan method prevails as well to determine whether or not a detected low voltage signal is a valid button-depressed signal.

This application claims the benefit of Taiwan Patent Application Serial No. 104132835, filed Oct. 6, 2015, the subject matter of which is incorporated herein by reference.

### BACKGROUND OF INVENTION

1. Field of the Invention

The invention relates to a scan method for keyboards, and more particularly to the scan method for keyboards that, in the case of different voltage settings to keyboard scan input/output contacts, can detect voltages of a keyboard scan input contact and a keyboard scan input/output contact so as further to determine whether or not a low voltage signal is a valid button signal.

2. Description of the Prior Art

Generally speaking, in the art of keyboard scan, the confirmation of the depressed button by the firmware in the conventional scan method is delayed by a switch bounce time, no matter what the detected signal is a keyboard signal or a noise.

Refer now to FIG. 1 and FIG. 2; which FIG. 1 is a schematic view of a circuit structure for a conventional button, and FIG. 2 is a voltage diagram showing schematically voltage responses upon when a conventional button is connected electrically to a keyboard scan input contact and a keyboard scan output contact. As shown, the conventional keyboard module PA100 is mainly to construct a button PA1 between a contact of the keyboard scan input port PAKSI and another contact of the keyboard scan output port PAKSO. While the button PA1 is depressed to connect electrically contacts of the keyboard scan input port PAKSI and the keyboard scan output port PAKSO, the keyboard scan input port PAKSI would generate a low voltage signal. At the time “t” after an oscillation time duration BT, a firmware would then scan to determine whether or not the low voltage signal os a valid signal from actions of the button PA1.

As described, since the voltage at the keyboard scan input port PAKSI would change while the button PA1 is depressed to bridge electrically the keyboard scan input port PAKSI and the keyboard scan output port PAKSO, and at this time the instant voltage response would experience oscillations for an oscillation time duration BT, the firmware is usually preset to scan and determine whether or not the detected voltage signal at the keyboard scan input port PAKSI is a valid button-depressed signal or a noise, after the oscillations in the oscillation time duration are over. Accordingly, the response time for button depressing is thus substantially delayed. Such a delay would definitely bother the user whom expects a swift or real-time response from his/her button action.

### SUMMARY OF THE INVENTION

In the art, when the firmware detects a low voltage signal is generated at the keyboard scan input port, a wait for the oscillation time duration is needed before a determination upon whether the low voltage signal is a valid button-depressed signal or a noise can be processed. Therefore, the response speed to the button depression is usually not satisfied.

Accordingly, it is the primary object of the present invention to provide a scan method for keyboards that can utilize the firmware to configure a voltage at the keyboard scan input/output contact and determine if a detected low voltage signal at the keyboard scan input contact is a valid button signal or a noise signal by judging the voltage variation.

In the present invention, the scan method for keyboards is applied to a keyboard module, which the keyboard module includes a keyboard scan input contact, a keyboard scan input/output contact, a button and a firmware. The button is electrically connected with the keyboard scan input contact and the keyboard scan input/output contact, and the firmware is electrically connected with the keyboard scan input contact and the keyboard scan input/output contact. The scan method comprises the steps of: (a) setting a voltage at the keyboard scan input/output contact to be an output voltage while the firmware detects a low voltage signal being generated by the keyboard scan input contact; (b) detecting if a voltage at the keyboard scan input contact is a low voltage or not; setting the voltage at the keyboard scan input/output contact to be an input voltage while the voltage at the keyboard scan input contact is the low voltage; and (c) detecting if the voltage at the keyboard scan input/output contact is a high voltage or not; determining the low voltage signal to be a button signal and performing a signal masking process within an oscillation time duration of the low voltage signal while the voltage at the keyboard scan input/output contact is the high voltage

In one embodiment of the present invention, in Step (c), the low voltage signal is judged to be a noise signal if the voltage at the keyboard scan input contact is the low voltage.

In another aspect of the present invention, the scan method for keyboards is applied to a keyboard module, which the keyboard module includes a keyboard scan input contact, a keyboard scan input/output contact, a button and a firmware. The keyboard scan input/output contact is connected electrically with a grounding resistor, the button is electrically connected with the keyboard scan input contact and the keyboard scan input/output contact, and the firmware is electrically connected with the keyboard scan input contact and the keyboard scan input/output contact. The scan method comprises the steps of: (a) setting a voltage at the keyboard scan input contact to be an input voltage while the firmware detects a low voltage signal being generated by the keyboard scan input contact; (b) detecting if a voltage at the keyboard scan input/output contact is a high voltage or not; setting the voltage at the keyboard scan input/output contact to be an output voltage while the voltage at the keyboard scan input/output contact is the high voltage; and (c) determining the low voltage signal to be a button signal and performing a signal masking process within an oscillation time duration of the low voltage signal while the voltage at the keyboard scan input contact is the low voltage.

In one embodiment of the present invention, the low voltage signal is judged to be a noise signal if the voltage at the keyboard scan input/output contact is the low voltage.

By compared to the conventional technique, since the scan method for keyboards provided by the present invention utilizes the firmware to perform setting and scanning at a circumstance of even adopting the used hardware, the response speed of the keyboard is significantly enhanced, and the noise interference to the keyboard can be effectively inhibited.

All these objects are achieved by the scan method for keyboards described below.

### BRIEF DESCRIPTION OF THE DRAWINGS

The present invention will now be specified with reference to its preferred embodiment illustrated in the drawings, in which:

FIG. 1 is a schematic view of a circuit structure for a conventional button;

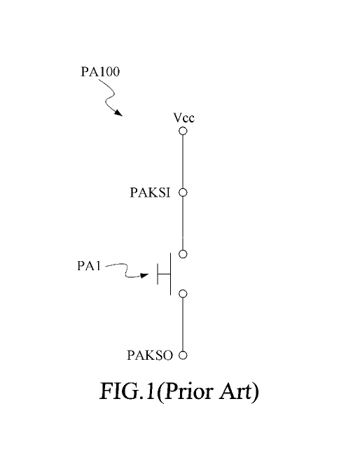

FIG. 2 is a voltage diagram showing schematically voltage responses upon when a conventional button is connected electrically to a keyboard scan input contact and a keyboard scan output contact;

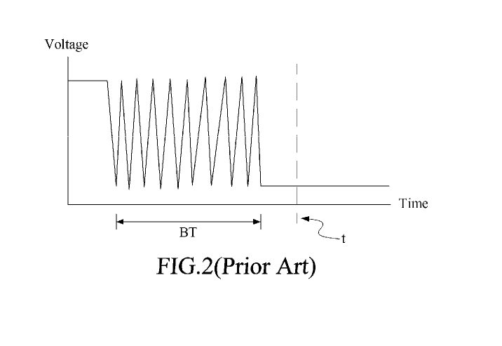

FIG. 3 is a block diagram of a first embodiment of the keyboard module in accordance with the present invention;

FIG. 4 is a schematic view of a circuit structure for FIG. 3;

FIG. 5 is a flowchart of a scan method for keyboards associated with the first embodiment of FIG. 3;

FIG. 6 is a voltage diagram showing schematically voltage responses at the keyboard scan input port upon when the button of FIG. 4 is depressed to connected electrically to the keyboard scan input contact and the keyboard scan input/output contact;

FIG. 7 is a block diagram of a second embodiment of the keyboard module in accordance with the present invention;

FIG. 8 is a schematic view of a circuit structure for FIG. 7; and

FIG. 9 is a flowchart of a scan method for keyboards associated with the second embodiment of FIG. 7.

### DESCRIPTION OF THE PREFERRED EMBODIMENT

The invention disclosed herein is directed to a scan method for keyboards. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

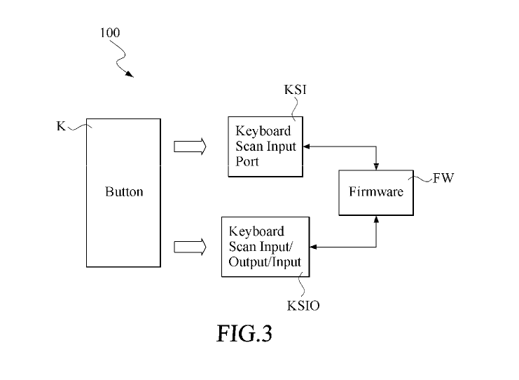

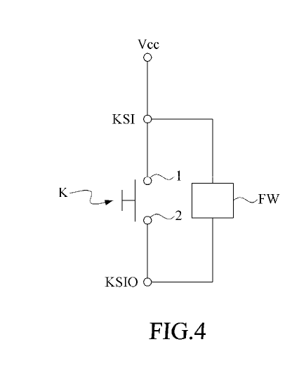

Refer now to FIG. 3 and FIG. 4; which FIG. 3 is a block diagram of a first embodiment of the keyboard module in accordance with the present invention, and FIG. 4 is a schematic view of a circuit structure for FIG. 3. As shown, a keyboard module 100 includes a keyboard scan input port KSI, a keyboard scan input/output port KSIO, a button K and a firmware FW. The keyboard scan input port KSI, connected electrically to a voltage source Vcc (Volt current condenser), has a keyboard scan input contact 1. The keyboard scan input/output port KSIO has a keyboard scan input/output contact 2. The button K is electrically connected with the keyboard scan input contact 1 and the keyboard scan input/output contact 2. The firmware FW is electrically connected individually with the keyboard scan input port KSI and the keyboard scan input/output port KSIO, and so is further electrically connected respectively to the keyboard scan input contact 1 and the keyboard scan input/output contact 2. In this embodiment, since the keyboard scan input port KSI is electrically coupled with the voltage source Vcc, thus a high voltage is purposely preset to the keyboard scan input port KSI as well as the keyboard scan input contact 1.

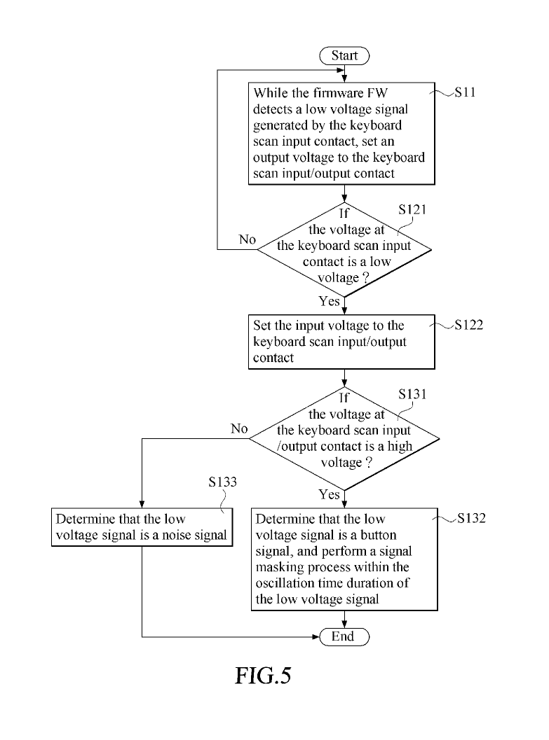

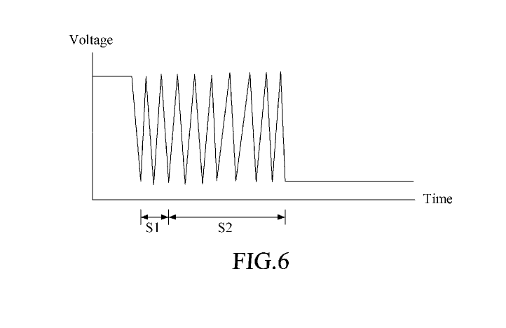

Refer now to FIG. 5 and FIG. 6; which FIG. 5 is a flowchart of a scan method for keyboards associated with the first embodiment of FIG. 3, and FIG. 6 is a voltage diagram showing schematically voltage responses at the keyboard scan input port upon when the button of FIG. 4 is depressed to connected electrically to the keyboard scan input contact and the keyboard scan input/output contact. As shown, the first embodiment of the scan method for keyboards in this invention is applied to the keyboard module 100 and includes the following steps. Firstly, in Step S11, while the firmware FW detects a low voltage signal generated by the keyboard scan input contact 1, the keyboard scan input/output contact 2 would then be set as an output voltage. In particular, this setting is performed at a first oscillation time zone S1 within the oscillation time duration of the firmware FW. Namely, at this time, the firmware FW sets the voltage at the keyboard scan input/output port KSIO as the output voltage. That is to say that the voltage at the keyboard scan input/output contact 2 is set to be the output voltage. Since the voltage at the keyboard scan input port KSI preset as the input voltage now becomes the high voltage, and the voltage at the keyboard scan input/output contact 2 preset as the output voltage now becomes the low voltage; thus, in the case that the button K is at a state to separate electrically the keyboard scan input contact 1 and the keyboard scan input/output contact 2, the keyboard scan input port KSI would be stayed at the high voltage while the voltage at the keyboard scan input/output contact 2 preset as the output voltage becomes the low voltage. On the other hand, in the case that the button K is at a state to connect electrically the keyboard scan input contact 1 and the keyboard scan input/output contact 2, the voltage at the keyboard scan input contact 1 would be the same as the voltage at the keyboard scan input/output contact 2, i.e. the low voltage.

Then, in Step S121, the voltage at the keyboard scan input contact 1 is detected to be a low voltage or not. In the case that the keyboard scan input contact 1 is at the low voltage, it implies, highly possible, that a depression upon the button K is applied so as to connect electrically the keyboard scan input contact 1 and the keyboard scan input/output contact 2, and so as to equal the voltages at the keyboard scan input contact 1 and the keyboard scan input/output contact 2 to be the same low voltage. Then, Step S122 is performed for confirmation. In Step 122, the voltage at the keyboard scan input/output contact 2 is set as the input voltage. In Step S131, the voltage at the keyboard scan input/output contact 2 is detected to be a high voltage or not. In the case that that the keyboard scan input/output contact 2 is at a state of high voltage, then perform Step S132. In Step S132, if the low voltage signal is judged to be a button signal is confirmed, and also a signal masking process is performed within the oscillation time duration of the low voltage signal so as to mask signals within a second oscillation time zone S2 of the oscillation time duration. In addition, in the case that the voltage at the keyboard scan input/output contact 2 is detected to be the low voltage in Step S131, then the low voltage signal is judged to be a noise signal.

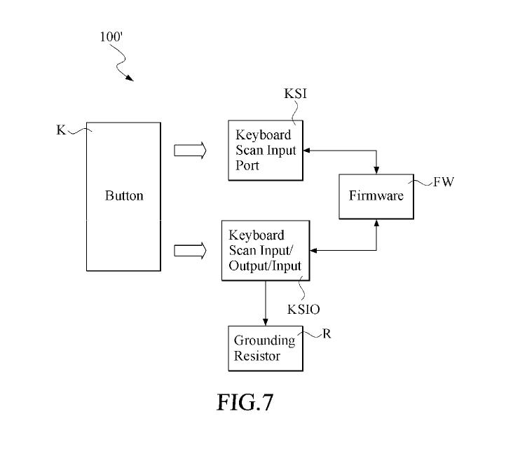

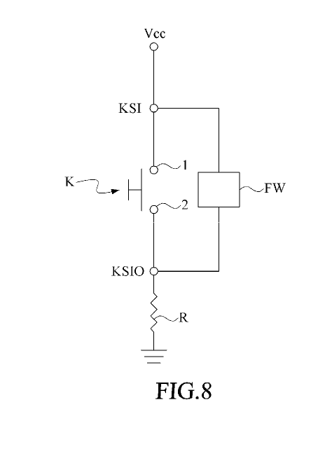

Refer now to FIG. 7 and FIG. 8; which FIG. 7 is a block diagram of a second embodiment of the keyboard module in accordance with the present invention, and FIG. 8 is a schematic view of a circuit structure for FIG. 7. As shown, a keyboard module 100′ of this second embodiment is resembled to the aforesaid keyboard module 100 of the first embodiment. A major difference in between is that the keyboard module 100′ of this second embodiment further includes a grounding resistor R electrically connected with the keyboard scan input/output port KSIO.

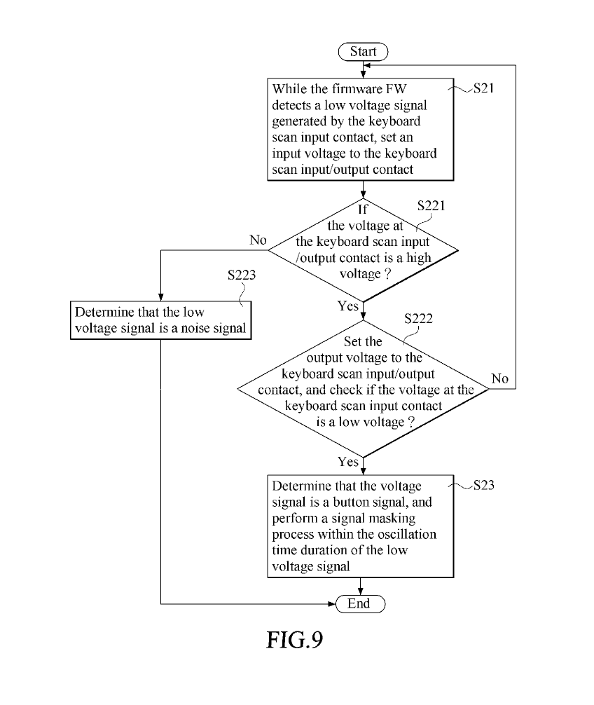

Referring now to FIG. 9, a flowchart of a scan method for keyboards associated with the second embodiment of FIG. 7 is provided. As shown, the second embodiment of the scan method for keyboards is applicable to the keyboard module 100′. The keyboard scan method includes the following steps. Firstly, in Step S21, while the firmware FW detects a low voltage signal generated by the keyboard scan input contact 1, the keyboard scan input/output contact 2 would then be set as an input voltage. Practically, the firmware FW is to set the voltage at the keyboard scan input/output port KSIO as the input voltage. Then, in Step S221, the voltage at the keyboard scan input/output contact 2 is detected to be a high voltage or not. In this embodiment, since the keyboard scan input/output contact 2 is set as the input voltage in Step S21, thus, in the case that the button K is depressed to connect electrically the keyboard scan input contact 1 and the keyboard scan input/output contact 2, the voltage at the keyboard scan input/output contact 2 would be held at the high voltage. On the other hand, in the case that the button K is not depressed so that the keyboard scan input contact 1 and the keyboard scan input/output contact 2 are not electrically connected, the voltage at the keyboard scan input/output contact 2 would be in a state of low voltage due to the connection with the grounding resistor R.

Then, in Step S221, while the voltage at the keyboard scan input/output contact 2 is detected to be a high voltage, then Step S222 is performed to set the voltage at the keyboard scan input/output contact 2 as the output voltage, and to check if the voltage at the keyboard scan input contact 1 is a low voltage or not. However, while, in Step S221, a low voltage is detected at the keyboard scan input/output contact, the firmware FW would directly determine that the low voltage signal generated at the keyboard scan input contact 1 is simply a noise signal.

As stated above, in the case that the firmware FW detects that the voltage at the keyboard scan input contact 1 is a low voltage in Step S222, then, in Step S23, the detected low voltage signal is judged to be a button signal generated at the keyboard scan input contact 1, and a signal masking process is performed within the oscillation time duration of the low voltage signal.

In summary, by compared to the conventional technique that the determination of the signal is definitely delayed by the oscillation time duration of the low voltage signal, the scan method for keyboards provided by the present invention can perform detecting, setting and determining early within the first oscillation time zone of the oscillation time duration, and masks the remaining signals in the second oscillation time zone after the low voltage signal is determined. Upon such an arrangement, the response time of the keyboard can be effectively reduced. Namely, even that the used hardware is still adopted, the scan method provided to the firmware in accordance with the present invention can still enhance the response speed of the keyboard and prohibit effectively the noise interference to the keyboard, without increasing the cost in hardware investment.

While the present invention has been particularly shown and described with reference to a preferred embodiment, it will be understood by those skilled in the art that various changes in form and detail may be without departing from the spirit and scope of the present invention.

What is claimed is:

1. A scan method for keyboards, applied to a keyboard module, the keyboard module including a keyboard scan input contact, a keyboard scan input/output contact, a button and a firmware, the button being electrically connected with the keyboard scan input contact and the keyboard scan input/output contact, the firmware being electrically connected with the keyboard scan input contact and the keyboard scan input/output contact, the scan method comprising the steps of:
(a) setting a voltage at the keyboard scan input/output contact to be an output voltage while the firmware detects a low voltage signal being generated by the keyboard scan input contact;
(b) detecting if a voltage at the keyboard scan input contact is a low voltage or not; setting the voltage at the keyboard scan input/output contact to be an input voltage while the voltage at the keyboard scan input contact is the low voltage; and
(c) detecting if the voltage at the keyboard scan input/output contact is a high voltage or not; determining the low voltage signal to be a button signal and performing a signal masking process within an oscillation time duration of the low voltage signal while the voltage at the keyboard scan input/output contact is the high voltage.

2. The scan method for keyboards of claim 1, wherein, in Step (c), the low voltage signal is judged to be a noise signal if the voltage at the keyboard scan input contact is the low voltage.

3. The scan method for keyboards of claim 1, wherein the keyboard module further includes a keyboard scan input port connecting electrically directly with the keyboard scan input contact.

4. The scan method for keyboards of claim 1, wherein the keyboard module further includes a keyboard scan input/output port connecting electrically directly with the keyboard scan input/output contact.

5. A scan method for keyboards, applied to a keyboard module, the keyboard module including a keyboard scan input contact, a keyboard scan input/output contact, a button and a firmware, the keyboard scan input/output contact being connected electrically with a grounding resistor, the button being electrically connected with the keyboard scan input contact and the keyboard scan input/output contact, the firmware being electrically connected with the keyboard scan input contact and the keyboard scan input/output contact, the scan method comprising the steps of:
(a) setting a voltage at the keyboard scan input contact to be an input voltage while the firmware detects a low voltage signal being generated by the keyboard scan input contact;
(b) detecting if a voltage at the keyboard scan input/output contact is a high voltage or not; setting the voltage at the keyboard scan input/output contact to be an output voltage while the voltage at the keyboard scan input/output contact is the high voltage; and
(c) determining the low voltage signal to be a button signal and performing a signal masking process within an oscillation time duration of the low voltage signal while the voltage at the keyboard scan input contact is the low voltage.

6. The scan method for keyboards of claim 5, wherein, in Step (b), the low voltage signal is judged to be a noise signal if the voltage at the keyboard scan input/output contact is the low voltage.

7. The scan method for keyboards of claim 5, wherein the keyboard module further includes a keyboard scan input port connecting electrically directly with the keyboard scan input contact.

8. The scan method for keyboards of claim 5, wherein the keyboard module further includes a keyboard scan input/output port connecting electrically directly with the keyboard scan input/output contact.
